(19) United States
(12) Patent Application Publication
(10) Pub. No.: US 2009/0142928 A1
(43) Pub. Date: Jun. 4, 2009

(54) MANUFACTURING METHOD OF SEMICONDUCTOR DEVICE

(76) Inventor: Rae-Hyuk Lee, Bucheon-si (KR)

Correspondence Address: SHERR & VAUGHN, PLLC, 620 HERNDON PARKWAY, SUITE 200, HERNDON, VA, 20170, US

(21) Appl. No.: 12/325,162

(22) Filed: Nov. 29, 2008

(30) Foreign Application Priority Data
Nov. 29, 2007 (KR) 10-2007-0122591

(51) Int. Cl. H01L 21/311

(52) U.S. Cl. 438/703; 257/E21.249

(57) ABSTRACT

A manufacturing method for a semiconductor device simplifies a process for forming an oxide film of a high-voltage device, thereby reducing the manufacturing costs and manufacturing time of the high-voltage device. The manufacturing method includes applying a gate oxide material over a semiconductor wafer, applying a photoresist material over the gate oxide material, performing an exposure process and a primary development process on the photoresist material to form a photoresist pattern, performing an etching process using the photoresist pattern to form a gate oxide film, and performing a secondary development process to remove the photoresist pattern.

The present application claims priority under 35 U.S.C. 119 to Korean Patent Application No. 10-2007-0122591 (filed on Nov. 29, 2007), which is hereby incorporated by reference in its entirety.

### BACKGROUND

Generally, a process for manufacturing a semiconductor device may be divided into a pre-process and a post-process. The pre-process may be carried out in the order of: oxidation, application of photoresist, exposure, development, etching, ion implantation, chemical vapor deposition, metallization, and wire bonding. The post-process, which is carried out after the pre-process, includes assembly and inspection. Specifically, the post-process may be carried out in the order of: a wafer EDS test, wafer sawing, chip die attachment, wire bonding, molding, and a final test. A high-voltage device or a low-voltage device may be formed on a wafer through the above-described processes. However, when a high-voltage device and a low-voltage device are formed on a single wafer, the manufacturing process becomes very complicated.

FIGS. 1A to 1C are process sectional views illustrating a related method of forming a gate oxide film of a high-voltage device. First, as shown in FIG. 1A, a gate oxide material layer 4a and a photosensitive film, e.g., a photoresist layer 6a, are sequentially formed over a semiconductor wafer 2. Here, the gate oxide material layer 4a may be used as a gate insulation layer of the high-voltage device. The gate oxide material layer 4a and the photoresist layer 6a are uniformly formed over the top of the semiconductor wafer 2 by a centrifugal force of a spin coating apparatus. Subsequently, a solvent is sprayed to the edge of the semiconductor wafer 2 to remove the photoresist layer 6a from the edge of the semiconductor wafer 2 (edge blade removal: EBR). In this way, a pre-exposure process is completed.

Subsequently, as shown in FIG. 1B, a mask is arranged, and an exposure process is carried out, to form a pattern. The exposed semiconductor wafer 2 is developed using a developer, such that the remaining portion of the photoresist layer 6a, excluding a selected portion of the photoresist layer 6a, forms a photoresist pattern 6. Subsequently, deionized water (DI water) is sprayed to the semiconductor wafer 2, to which the developer has been sprayed, to wash the semiconductor wafer 2, and then the washed semiconductor wafer 2 is dried. The residual solution is removed from the developed photoresist pattern 6, and, at the same time, a hard baking process is carried out to improve bonding strength and morphology of the photoresist pattern 6.

Subsequently, as shown in FIG. 1C, a wet etching process using buffered hydrogen fluoride (BHF) is carried out at a temperature of 24° C. to 25° C. to form a gate oxide film 4 over the semiconductor wafer 2. Subsequently, a development process using a developer is carried out to remove the photoresist pattern 6, and then washing and drying processes are carried out such that only the gate oxide film 4 is left over the semiconductor wafer 2.

However, the related method of forming the gate oxide film of the high-voltage device has problems. After forming the photoresist pattern 6, various processes, such as the washing process, the drying process, and the hard baking process, must be carried out to form the gate oxide film 4. This increases the manufacturing time and manufacturing costs of the high-voltage device.

### SUMMARY

Embodiments relate to a manufacturing method of a semiconductor device, and more particularly, to a manufacturing method of a semiconductor device that simplifies a process for forming an oxide film of a high-voltage device, thereby reducing manufacturing costs and manufacturing time for high-voltage devices.

Embodiments relate to a manufacturing method of a semiconductor device that simplifies a process for forming an oxide film for a high-voltage device, thereby reducing the manufacturing costs and manufacturing time of high-voltage devices.

Embodiments relate to a manufacturing method of a semiconductor device which includes applying a gate oxide material over a semiconductor wafer, applying a photoresist material over the gate oxide material, performing an exposure process and a primary development process on the photoresist material to form a photoresist pattern, performing an etching process using the photoresist pattern to form a gate oxide film, and performing a secondary development process to remove the photoresist pattern. In accordance with embodiments, forming the gate oxide film may include performing a wet etching process using buffered hydrogen fluoride (BHF) at a temperature of 24° C. to 25° C. The secondary development process may be performed using at least one selected from a group consisting of sulfuric acid, ozone, and a hyperhydric solution. In accordance with embodiments, removing the photoresist pattern may include performing the secondary development process using at least one selected from a group consisting of sulfuric acid, ozone, and a hyperhydric solution, without additional washing, drying, and hard baking processes, after forming the gate oxide film.

Embodiments relate to a method that may include at least one of the following: applying a gate oxide material over a semiconductor wafer; and then applying a photoresist material over the gate oxide material; and then performing an exposure process and a primary development process on the photoresist material to form a photoresist pattern; and then performing an etching process using the photoresist pattern to form a gate oxide film; and then performing a secondary development process to remove the photoresist pattern.

Embodiments relate to a method that may include at least one of the following: forming an oxide material over a semiconductor wafer; and then forming a photoresist material over the oxide material; and then forming a photoresist pattern by performing an exposure process and a primary development process on the photoresist material; and then forming a gate oxide film by performing an etching process on the oxide film using the photoresist pattern as a mask; and then removing the photoresist pattern by performing a secondary development process after forming the gate oxide film.

### DRAWINGS

FIGS. 1A to 1C are process sectional views illustrating a related method of forming a gate oxide film of a high-voltage device.

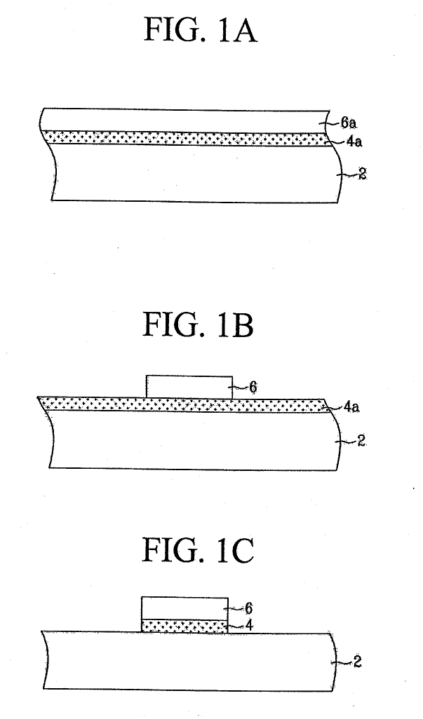

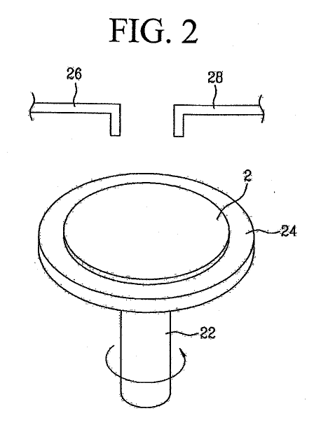

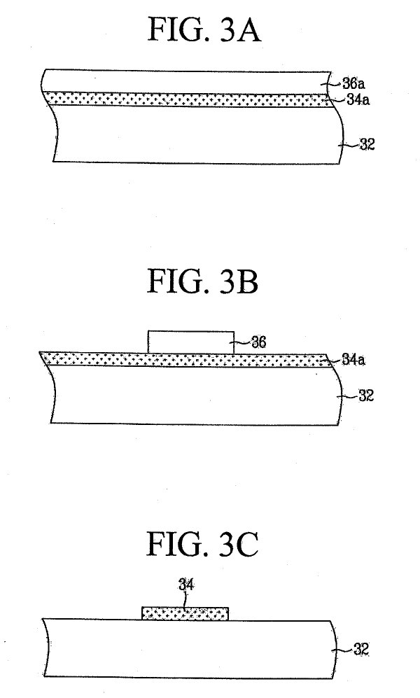

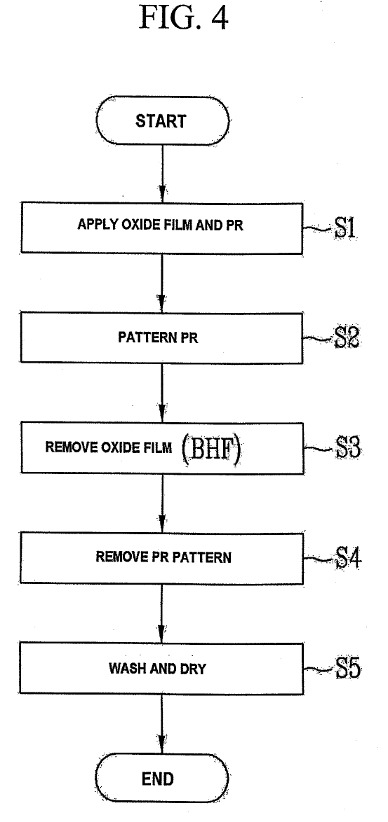

Example FIGS. 2 to 4 illustrate an apparatus for manufacturing a high-voltage device, a method of forming a gate oxide film of a high-voltage device and a manufacturing method of a high-voltage device according to embodiments.

### DESCRIPTION

Example FIG. 2 is a constructional view illustrating an apparatus for manufacturing a high-voltage device according to embodiments. The manufacturing apparatus shown in example FIG. 2 includes a rotary chuck 24 on which a semiconductor wafer 2 is mounted, a rotary shaft 22 to rotate the rotary chuck 24, a chemical materials (depositing and etching materials) spray nozzle 26, and an ultra pure solution spray nozzle 28. The manufacturing apparatus may further include a LIC-3 spray nozzle and an N₂ gas spray nozzle. The manufacturing apparatus sprays chemical materials, the ultra pure solution, and the N2 gas through the LIC-3 spray nozzle, the chemical materials (depositing and etching materials) spray nozzle 26, the N₂ gas spray nozzle, and the ultra pure solution spray nozzle 28, provided at a susceptor. Also, the manufacturing apparatus may further include a power flange connected to a susceptor provided at a general single type apparatus to move the susceptor upward or downward, a SUS chamber including a quartz dome to surround the susceptor and the power flange, a bell jar heater to adjust the process temperature in the SUS chamber, a slot valve configured to be opened or closed depending upon the introduction and withdrawal of the semiconductor wafer 2, and a vacuum pump to create vacuum in the SUS chamber.

Example FIGS. 3A to 3C are process sectional views illustrating a method of forming a gate oxide film of a high-voltage device according to embodiments, and example FIG. 4 is a flow chart illustrating a manufacturing method of a high-voltage device according to embodiments. First, as shown in example FIG. 3A, a semiconductor wafer 32, to which a gate oxide material 34a and a photoresist material 36a will be applied, may be placed on the spin chuck 24. A hexamethyl-idisilane (HMDS) process may be carried out on the semiconductor wafer 2 such that a gate oxide material or a photoresist material for semiconductor wafer lithography can be attached effectively to the surface of the semiconductor wafer 2. The semiconductor wafer 2 may be cooled to a predetermined temperature. The spin chuck 24 is rotated to provide a centrifugal force to the semiconductor wafer 2. Subsequently, a gate oxide material 34a may be applied to the semiconductor wafer 2. The gate oxide material 34a may be uniformly coated over the entire surface of the semiconductor wafer 2 by centrifugal force. After the gate oxide material 34a is cured, a photoresist material 36a may be applied to the cured gate oxide material 34a. The photoresist material 36a may be uniformly coated over the entire surface of the gate oxide material 34a by the centrifugal force. Subsequently, a solvent may be sprayed to the edge of the semiconductor wafer 2 to remove the photoresist layer 36a from the edge of the semiconductor wafer 2 (edge blade removal). In this way, a pre-exposure process is completed (S1).

Subsequently, as shown in example FIG. 3B, a mask may be arranged, and an exposure process is carried out, to form a pattern. The exposed semiconductor wafer 2 is developed using a developer, and the remaining portion of the photoresist layer 36a, excluding a selected portion of the photoresist layer 6a, i.e., the pattern portion of the photoresist layer 6a, forms a photoresist pattern 36 (S2). An optical edge blade removal (OEBR) process may be carried out, by an additional OEBR apparatus, to more securely remove the photoresist layer 36a from the edge of the semiconductor wafer 2, during or after the exposure process.

Subsequently, as shown in example FIG. 3C, a wet etching process using buffered hydrogen fluoride (BHF) may be carried out at a temperature of 24° C. to 25° C. to form a gate oxide film 34 over the semiconductor wafer 2. That is, the remaining portion of the gate oxide material 34a excluding a portion of the gate oxide material 34a corresponding to the photoresist pattern 36 may be removed to form the gate oxide film 34 (S3). A development process using at least one selected from a group consisting of sulfuric acid, ozone, and a hyperhydric solution may be carried out to remove the photoresist pattern 36 (S4). Washing and drying processes may be carried out. Only the gate oxide film 34 is left on the semiconductor wafer 2 (S5).

In the manufacturing method of the semiconductor device according to embodiments as described above, after performing the process for forming the photoresist pattern 36 (S2), the remaining portion of the gate oxide material 34a excluding a portion of the gate oxide material 34a corresponding to the photoresist pattern 36 may be removed, without additional washing, drying, and hard baking processes, to form the gate oxide film 34 (S4). Subsequently, the development process using at least one selected from a group consisting of sulfuric acid, ozone, and a hyperhydric solution may be carried out (S4) to leave only the gate oxide film 34 on the semiconductor wafer 2.

According to embodiments, as described above, the process for forming the gate oxide film 34 of a high-voltage device is simplified. Therefore, the manufacturing costs and manufacturing times for high-voltage devices are reduced. The manufacturing method of the semiconductor device according to embodiments has the effect of simplifying a process for forming the oxide film of high-voltage devices, thereby reducing manufacturing costs and manufacturing times.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method comprising:
applying a gate oxide material over a semiconductor wafer; and then
applying a photoresist material over the gate oxide material; and then
performing an exposure process and a primary development process on the photoresist material to form a photoresist pattern; and then
performing an etching process using the photoresist pattern to form a gate oxide film; and then
performing a secondary development process to remove the photoresist pattern.

2. The method of claim 1, wherein forming the gate oxide film includes performing a wet etching process using buffered hydrogen fluoride.

3. The method of claim 2, wherein performing the wet etching process using buffered hydrogen fluoride proceeds at a temperature in a range between approximately 24° C. to 25° C.

4. The method of claim 1, wherein the secondary development process is performed using at least one selected from a group consisting of sulfuric acid, ozone, and a hyperhydric solution.

5. The method of claim 1, wherein performing the secondary development process includes using at least one selected from a group consisting of sulfuric acid, ozone, and a hyperhydric solution, without additional washing, drying, and hard baking processes, after forming the gate oxide film.

6. The method of claim 1, further comprising:
prior to applying the gate oxide material over the semiconductor wafer, placing the semiconductor wafer on a spin chuck.

7. The method of claim 1, further comprising:
prior to applying the gate oxide material over the semiconductor wafer, performing a hexamethyl-idisilane process on the semiconductor wafer.

8. The method of claim 1, further comprising:
after applying the photoresist material over the gate oxide material,
performing an edge blade removal process for spraying a solvent at the edge of the semiconductor wafer to remove the photoresist material from the edge of the semiconductor wafer.

9. The method of claim 1, further comprising:
after performing the exposure process and the primary development process on the photoresist material to form the photoresist pattern, performing an optical edge blade removal process to remove the photoresist material from the edge of the semiconductor wafer.

10. The method of claim 1, further comprising:
carrying out washing and drying processes only after performing the secondary development process to remove the photoresist pattern.

11. A method comprising:
forming an oxide material over a semiconductor wafer; and then
forming a photoresist material over the oxide material; and then
forming a photoresist pattern by performing an exposure process and a primary development process on the photoresist material; and then
forming a gate oxide film by performing an etching process on the oxide film using the photoresist pattern as a mask; and then
removing the photoresist pattern by performing a secondary development process after forming the gate oxide film.

12. The method of claim 11, wherein the etching process comprises a wet etching process that includes buffered hydrogen fluoride.

13. The method of claim 12, wherein the etching process comprises performing a wet etching process using buffered hydrogen fluoride at a temperature in a range between approximately 24° C. to 25° C.

14. The method of claim 11, wherein the secondary development process is performed using at least one selected from a group consisting of sulfuric acid, ozone, and a hyperhydric solution.

15. The method of claim 11, wherein the secondary development process is performed using at least one selected from a group consisting of sulfuric acid, ozone, and a hyperhydric solution, without additional washing, drying, and hard baking processes, after forming the gate oxide film.

16. The method of claim 11, further comprising before forming the oxide material, holding the semiconductor wafer on a spin chuck.

17. The method of claim 11, further comprising before forming the oxide material, performing a hexamethyl-idisilane process on the semiconductor wafer prior.

18. The method of claim 11, further comprising after forming the photoresist material, performing an edge blade removal process for spraying a solvent at the edge of the semiconductor wafer to remove the photoresist material from the edge of the semiconductor wafer.

19. The method of claim 11, further comprising after forming a photoresist pattern, performing an optical edge blade removal process to remove the photoresist material from the edge of the semiconductor wafer.

20. The method of claim 11, further comprising after removing the photoresist pattern, performing washing and drying processes.
